(19) United States
(12) Patent Application Publication
(10) Pub. No.: US 2022/0285571 A1
(43) Pub. Date: Sep. 8, 2022

(54) NANO-ENGINEERED THIN-FILM THERMOELECTRIC CONVERTER FOR PHOTOVOLTAIC APPLICATIONS

(71) Applicant: The Johns Hopkins University, Baltimore, MD (US)

(72) Inventors: Rama Venkatasubramanian, Cary, NC (US); Meiyong Himmtann, Sykesville, MD (US); Priyadharshini Gajendiran, Ellicott City, MD (US); Jonathan M. Pierce, Eldersburg, MD (US); Nathan J. Fairbanks, Montgomery Village, MD (US); Richard J. Ung, Columbia, MD (US); Jacob L. Ballard, Elkridge, MD (US); Jeffrey P. Maranchi, Clarksburg, MD (US)

(21) Appl. No.: 17/686,788

(22) Filed: Mar. 4, 2022

Related U.S. Application Data
(60) Provisional application No. 63/158,015, filed on Mar. 8, 2021.

(51) Int. Cl. H01L 31/052; H01L 35/16; H01L 31/0687; H01L 25/16; H01L 31/18

(52) U.S. Cl. CPC H01L 31/052; H01L 35/16; H01L 31/0687; H01L 25/16; H01L 31/18; B82Y 30/00

(57) ABSTRACT

Systems, apparatuses, and methods are provided for manufacturing nano-engineered thin-film thermoelectric (NETT) devices for photovoltaic applications, such as NETT converters that harness the coldness of space for satellite applications or for integration with terrestrial PV. An example method can include mounting a thin-film thermoelectric device to a photovoltaic device. The example method can further include mounting a heat sink device to the thin-film thermoelectric device. The example method can further include mounting a radiator device or heat exchanger device to the heat sink device.

### CROSS-REFERENCE TO RELATED APPLICATIONS

The present application claims priority to U.S. Provisional Application No. 63/158,015, filed Mar. 8, 2021, and titled “Nano-engineered Thin-film Thermoelectric Converter Harnessing the Coldness of Space for Satellite Applications,” the content of which is incorporated by reference herein in its entirety.

### STATEMENT REGARDING FEDERALLY SPONSORED RESEARCH OR DEVELOPMENT

The present application was made with U.S. Government support. The Government has certain rights in the invention.

### BACKGROUND

Today's satellite power systems use photovoltaics to power the operations—from communications to weather monitoring to broadcast TV, internet service provision and reconnaissance. Space multi junction photovoltaics (MJPV) devices offer an efficiency of approximately 30%, with typical MJPV cell heat-sink radiator temperatures running at about 345 Kelvin (K), with the sun-facing photovoltaic (PV) devices approaching about 350 K. The 30% efficiency of MJPV implies that about 70% of the incoming solar energy is rejected as waste heat from the radiator, and the 70% incoming solar energy goes unutilized. This can also be true in terrestrial PV systems, where the most common flat-plate (i.e., no concentration of sunlight) PV technology made of Si solar cells is about 20% efficient and hence 80% of the incoming solar energy goes unutilized as waste heat. Similarly, in other flat-plate PV systems like those based on amorphous-Si, single crystal Si, or polycrystalline PV materials like CdTe or copper indium gallium diselenide (CIGS), the efficiency of PV conversion is even lower (˜10% to 15%) such that 90% to 85% of the incoming solar energy goes unutilized as waste heat. Concentrator PV systems in terrestrial situation can approach 35 to 45% efficient, and so about 65% to 55% of incoming solar energy goes unutilized as waste heat.

### SUMMARY

The present disclosure describes various aspects of systems, apparatuses, and methods for manufacturing nano-engineered thin-film thermoelectric (NETT) devices for photovoltaic applications, such as MJPV-plus-NETT (MJPV-NETT) devices that harness the coldness of space for satellite applications or for improving the efficiency of terrestrial solar PV systems.

In some aspects, the present disclosure describes a method for manufacturing a NETT device for photovoltaic applications. The method can include mounting a thin-film thermoelectric device onto a photovoltaic device. The method can further include mounting a heat sink device to the thin-film thermoelectric device. The method can further include mounting a radiator device to the heat sink device.

In some aspects, the present disclosure describes a NETT device manufactured according to any of the methods described herein or combinations thereof.

In some aspects, the present disclosure describes an apparatus. The apparatus can include a photovoltaic device. The apparatus can further include a thin-film thermoelectric device mounted to the photovoltaic device. The apparatus can further include a heat sink device mounted to the thin-film thermoelectric device. The apparatus can further include a radiator device mounted to the heat sink device.

Further features, as well as the structure and operation of various aspects, are described in detail below with reference to the accompanying drawings. It is noted that the disclosure is not limited to the specific aspects described herein. Such aspects are presented herein for illustrative purposes only. Additional aspects will be apparent to persons skilled in the relevant art(s) based on the teachings contained herein.

### BRIEF DESCRIPTION OF THE DRAWINGS

The accompanying drawings, which are incorporated herein and form part of the specification, illustrate the present disclosure and, together with the description, further serve to explain the principles of the aspects of this disclosure and to enable a person skilled in the relevant art(s) to make and use the aspects of this disclosure.

FIGS. 1A, 1B, 1C, and 1D are schematic illustrations of example process flow steps for fabricating an example MJPV-NETT device according to some aspects of the present disclosure.

FIG. 2 is a schematic illustration of an example MJPV-NETT device according to some aspects of the present disclosure.

FIG. 3 is an example method for manufacturing NETT devices for photovoltaic applications according to some aspects of the present disclosure or portion(s) thereof.

FIG. 4 shows a graph of power output data of power-generating devices disclosed herein, according to some embodiments.

The features and advantages of the present disclosure will become more apparent from the detailed description set forth below when taken in conjunction with the drawings, in which like reference characters identify corresponding elements throughout. In the drawings, unless otherwise indicated, like reference numbers generally indicate identical, functionally similar, and/or structurally similar elements. Additionally, generally, the left-most digit(s) of a reference number identifies the drawing in which the reference number first appears. Unless otherwise indicated, the drawings provided throughout the disclosure should not be interpreted as to-scale drawings or as the only approach to implementation of the disclosure rather than an example approach.

### DETAILED DESCRIPTION

This specification discloses one or more embodiments that incorporate the features of the present disclosure. The disclosed embodiment(s) merely describe the present disclosure. The scope of the disclosure is not limited to the disclosed embodiment(s). The breadth and scope of the disclosure are defined by the claims appended hereto and their equivalents.

The embodiment(s) described, and references in the specification to “one embodiment,” “an embodiment,” “an example embodiment,” etc., indicate that the embodiment(s) described can include a particular feature, structure, or characteristic, but every embodiment may not necessarily include the particular feature, structure, or characteristic. Moreover, such phrases are not necessarily referring to the same embodiment. Further, when a particular feature, structure, or characteristic is described in connection with an embodiment, it is understood that it is within the knowledge of one skilled in the art to affect such feature, structure, or characteristic in connection with other embodiments whether or not explicitly described.

Spatially relative terms, such as “beneath,” “below,” “lower,” “above,” “on,” “upper” and the like, may be used herein for ease of description to describe one element or feature's relationship to another element(s) or feature(s) as illustrated in the figures. The spatially relative terms are intended to encompass different orientations of the device in use or operation in addition to the orientation depicted in the figures. The device can be otherwise oriented (rotated 90 degrees or at other orientations) and the spatially relative descriptors used herein may likewise be interpreted accordingly.

The term “about” as used herein indicates the value of a given quantity that can vary based on a particular technology. Based on the particular technology, the term “about” can indicate a value of a given quantity that varies within, for example, 10-30% of the value (e.g., ±10%, ±20%, or ±30% of the value).

### Overview

In one example, high-efficiency and reliable electric power in satellite systems, from small cubesats to large satellites, is key to their capabilities. In some examples, power in high-performance satellites is generated by advanced MJPV devices that offer an efficiency of approximately 30%, with MJPV cell heat-sink radiator temperatures running at about 345 K, and with the sun-facing PV devices approaching about 350 K. In some examples, efficiencies of advanced MJPV devices are saturating around 30% under AM0 sunlight conditions, and the MJPV technology components and complexity are increasing. Here AM0 refers to the incoming solar radiation in space environment around the earth. Typically, satellites orbiting around the earth receive AM0 sunlight. In some embodiments, there is a need to make an innovative and disruptive departure from this paradigm and achieve markedly higher efficiencies to enable future capabilities of satellites.

The same concept can also apply to a PV device operating in terrestrial systems. The incoming solar radiation on land is referred to as AM1.5. Depending on the technology used, the efficiency of conversion can be 10% (amorphous Si), 15% (polycrystalline CdTe and CIGS), 20% (polycrystalline Si), 25% (single crystal Si), 35% (MJPV based on GaAs materials) in so-called 1-sun flat-plate systems, or the like. The efficiency can approach 45% in 100 to 500-sun concentrator MJPV systems. Flat-plate PV systems can include those based on amorphous-Si, single crystal Si, or polycrystalline PV materials like CdTe or CIGS. Concentrator PVs can include PV systems that use lenses or curved mirrors to focus sunlight onto smaller, highly efficient, multi junction solar cells.

In some aspects, advanced nano-engineered thin-film thermoelectric (NETT) materials and devices provide for a broad range of heat-to-electric conversion applications to harness many kinds of waste heat.

In some aspects, the NETT devices can be combined with MJPV devices or other PV devices in terrestrial systems.

In some aspects, the NETT materials and devices can include controlled hierarchical engineered superlattice structure (CHESS) thermoelectric structures or materials. In some aspects, the CHESS structures or materials can include p-type CHESS (P-CHESS) thermoelectric structures and n-type CHESS (N-CHESS) thermoelectric structures. In some aspects, a pair of thermoelectric structures can include a P-CHESS thermoelectric structure and an N-CHESS thermoelectric structure.

Various CHESS thermoelectric structures, materials, and fabrication techniques are described in more detail in U.S. patent application Ser. No. 17/132,640, filed Dec. 23, 2020, and titled “Superlattice Structures for Thermoelectric device modules”; U.S. Pat. No. 10,903,139, issued Jan. 26, 2021, and titled “Superlattice structures for thermoelectric device modules;” U.S. Provisional Application No. 62/420,815, filed Nov. 11, 2016, and titled “Controlled Hierarchical Engineered Superlattice Structures (CHESS) for High-Performance Thin-Film Thermoelectric device modules”; and U.S. Provisional Application No. 63/213,886, filed Jun. 23, 2021, and titled “Large Area Scalable Fabrication Methodologies for Versatile Thin-Film Thermoelectric Device Modules”; U.S. patent application Ser. No. 17/575,727, filed Jan. 14, 2022, and titled “Large Area Scalable Fabrication Methodologies for Versatile Thin-Film Thermoelectric Device Modules”; the content of each of which is incorporated by reference herein in its entirety. It will be understood that the CHESS layers disclosed herein can be fabricated on any suitable substrate, such as GaAs, silicon (Si), germanium (Ge), sapphire, etc. In some aspects, the CHESS layers disclosed herein can be grown on GaAs wafers and then transferred to a carrier wafer, where the GaAs can be selectively etched, leaving the thermoelectric films intact. As a result, GaAs may not be present in the final thermoelectric device module. In some aspects, the carrier wafer can include glass, silicon carbide (SiC), aluminum nitride (AlN), alumina (Al₂O₃), silicon (Si), or a flexible material such as Kapton® (poly (4, 4′-oxydiphenylene pyromellitimide)). As used herein, the term “semiconductor material” can include, but is not limited to, Bi₂Te₃, Sb₂Te₃, Bi₂Te₃₋ₓSeₓ, Sb₂₋ₓBiₓTe₃, Bi, Sb, PbTe, PbSe, PbTe₁₋ₓSeₓ, PbS, PnSnTe, Si, Ge, SiₓGe₁₋ₓ, or any other suitable material or combination thereof.

Aspects of the disclosure provide for applications of NETT materials and devices for higher satellite power system efficiency and reliability, including at least three high-value and innovative opportunities for these NETT devices in space satellite power systems to harness the coldness of outer space: (i) satellite power systems; (ii) distributed power for satellite health monitoring systems or emergency; and (iii) on-demand power for satellite operational needs.

Aspects of the disclosure also provide for applications of NETT materials and devices for higher terrestrial PV sunlight-to-electric conversion efficiency.

1. Development of a MJPV-NETT Integrated Higher Efficiency Converter to Harness the Coldness of Space.

As discussed above, in some examples, advanced MJPV devices having multiple junctions are approaching about 30% efficiency in AM0 sunlight and 0% efficiency during eclipse. The 30% efficiency rate associated with advanced MJPV devices may imply that about 70% of the incoming solar energy is rejected as waste heat from the radiator. In some aspects, the present disclosure describes advanced thin-film thermoelectric (TE) based energy harvesting techniques and devices for size, weight, and power (SWaP) optimized performance in satellite systems to enable increased energy efficiencies and capabilities. For example, NETT devices, when deployed between the heat-sink of the MJPV and a colder radiator at 170 K, can potentially generate an efficiency of about 12% with the waste heat of 70%. Thus, a net efficiency of about 8.4% (about 12% of 70%) can be added, resulting in an overall power conversion efficiency of about 38.4%. In some aspects, the NETT thin-film TE modules add negligible weight and have very high specific power. As a result, the MJPV-NETT integrated devices disclosed herein can substantially increase the performance of satellite solar power systems beyond what may be achievable from adding more junctions to MJPV devices, which can significantly impact the range of satellite capabilities.

In some embodiments, in typical low earth orbit (LEO), satellites and other spacecraft experience about two-thirds of their time in sunlight and one-third of their time in darkness. In some aspects, enabling any power output during the eclipse as well as higher efficiency during the light allows more satellite operations to occur during eclipse periods. Note that the temperature of the solar array front during eclipse can range from about 120 K to 180 K.

In some aspects, whereas advanced MJPV devices can provide about 30% efficiency in AM0 sunlight and 0% efficiency during eclipse, the MJPV-NETT devices disclosed herein can provide about 38% efficiency in AM0 sunlight and 12% efficiency during eclipse (with illumination coming from, for example, earth albedo, scattered sunlight, and earth infrared (IR) radiation).

2. Deployment of NETT Energy Harvester Thermal Blankets and Satellite Surfaces for Distributed Power for Satellite Health Monitoring Sensors.

In some aspects, the NETT devices disclosed herein can also be utilized to harness power in different applications, such as between the cold thermal blankets (about 120 K to 170 K not facing the sun depending on satellite orbit) that many satellites and spacecraft use, and the inner temperatures of 300 K. This approach can provide small, but valuable, distributed power for a variety of the sensors on the body of the satellite or spacecraft, without being dependent on the main PV array and having to run electrical bus lines that are prone to failure. For example, such distributed sensors can detect if the satellites have been hit by a particle, laser beam, etc. These NETT devices can be dropped into existing platforms and provide small scale power for diagnostics and satellite health monitoring. In one example, the efficiency of thin-film thermoelectric generator (TEG) when Tₕₒₜ is about 465 K and T_{cold} is about 305 K is about 6.5%. However, the efficiency may become higher when T_{cold} becomes smaller, for the same ΔT=Tₕₒₜ−T_{cold}, from the Carnot efficiency term. As a result, the expected efficiency is greater than 12% and, in some aspects, well-over 20%. These distributed NETT power sources can power sensors on satellites surfaces in a much more rugged way, without running power lines from the bus to the sensors. For example, NETT multi-couple modules can be used for energy harvesting between the coldness of about 120 K (e.g., typical surface temperatures when not facing the sun) and the inner temperatures of a satellite (e.g., about 300 K) for powering health monitoring sensors.

3. NETT Energy Harvester for Emergency Power or Extra On-Demand Power.

In some aspects, there may be situations when dependence on battery power during eclipse periods of a satellite can be called into question. For example, the recent fears of explosion risk from DirecTV's Spaceway−1 satellite due to a damaged battery, where an unexplained anomaly caused “significant and irreversible thermal damage” to Spaceway−1's batteries. Damaged batteries can be at high risk of bursting if recharged since the damaged cells cannot be isolated. In situations like these, when batteries are no longer functional during eclipse periods, fuel in the satellite could be controllably burnt continuously, even as the inside ambient temperature of the satellite is maintained at around 300 K. If so, the delta between the temperature of heat source (about 400 K) and outer space temperatures (about 120 K) can be harnessed. Lightweight, thin-film NETT modules can be deployed on surfaces of satellites for power generation with very high specific power (e.g., much greater than 250 W/kg) and potential efficiencies may approach 16%. For example, NETT multi-couple modules can be used for energy harvesting between the coldness of about 120 K and heat generated by on-board fuel at about 400 K for emergency power during battery failure or for extra on-demand power.

In some aspects, thermal-to-electric conversion data of the NETT devices has been demonstrated for a ΔT of about 150 K, with a ZT of about 1.0 to 1.4, and a T_{cold} of about 305 K, resulting in an electric power density of about 2,000 mW/cm² (about 2 W/cm²), and leading to high specific power. In some aspects, the NETT devices disclosed herein can be used for harnessing the temperature differentials with the “cold temperatures of space” for much higher efficiencies. In some examples, the higher efficiencies are enabled by the higher intrinsic thermodynamic Carnot efficiencies at colder temperatures. The efficiency of TE conversion, for a similar temperature differential of about 50 K to 150 K, dramatically improves when the cold side temperature (T_{cold}) is lowered. This can be understood from the dependence of efficiency (ηₘₐₓ) on the cold side temperature (T_{cold}) as shown in Equation 1 below, where the thermoelectric figure of merit (ZT) represents the average across the full temperature range between Tₕₒₜ and T_{cold}:

$$\begin{matrix}{η}_{max} = ( \frac{{T}_{h o t} - {T}_{c o l d}}{{T}_{h o t}} ) ( \frac{\sqrt{1 + \overline{ZT}} - 1}{\sqrt{1 + \overline{ZT}} + \frac{{T}_{cold}}{{T}_{h o t}}} ) \\ = ( \frac{Δ T}{{T}_{c o l d} + Δ T} ) ( \frac{\sqrt{1 + \overline{ZT}} - 1}{\sqrt{1 + \overline{ZT}} + \frac{{T}_{cold}}{{T}_{cold} + Δ T}} )\end{matrix} \qquad ( 1 )$$

In one illustrative and non-limiting example, the world's satellite systems play a crucial role in providing valuable information for military to commercial communications. The aspects described herein represent disruptive, high potential payoff technologies in innovative system designs that dramatically improve satellite systems, operations, and resilience with specific improvements in size, weight, power, and cost Size, Weight, Power and Cost (SWaP-C) for satellite components such as power systems, propulsion, satellite health monitoring, and increased power for onboard processing, or the like. The aspects described herein provide a high pay-off technology by creating a quantum-jump in efficiency of satellite power systems, while also addressing the system design operational health and resiliency under a variety of situations. In some embodiments, the NETT-plus-MJPV technologies, as well as stand-alone NETT technologies harnessing the coldness of space effectively, offer significant performance and resiliency enhancements for space satellites operating in a range of demanding, extreme, and unpredictable environments as well as for increased power for higher-performance satellites.

### Example Processes for Thermoelectric Device Fabrication

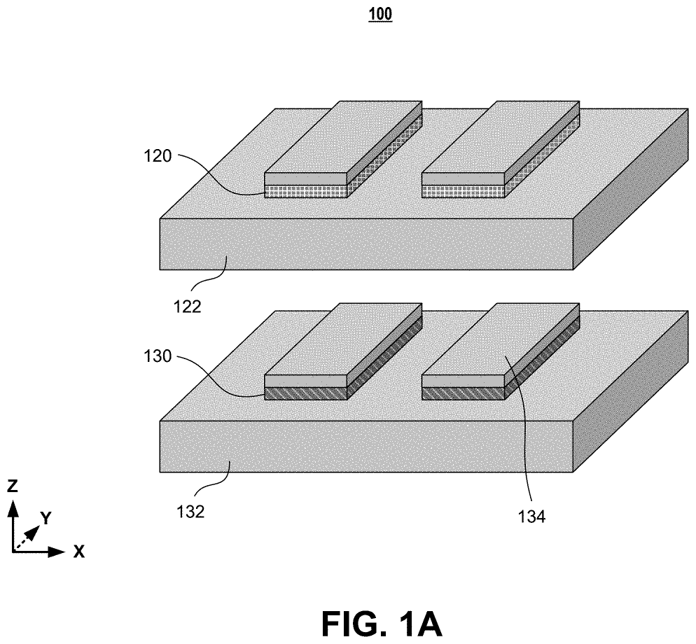

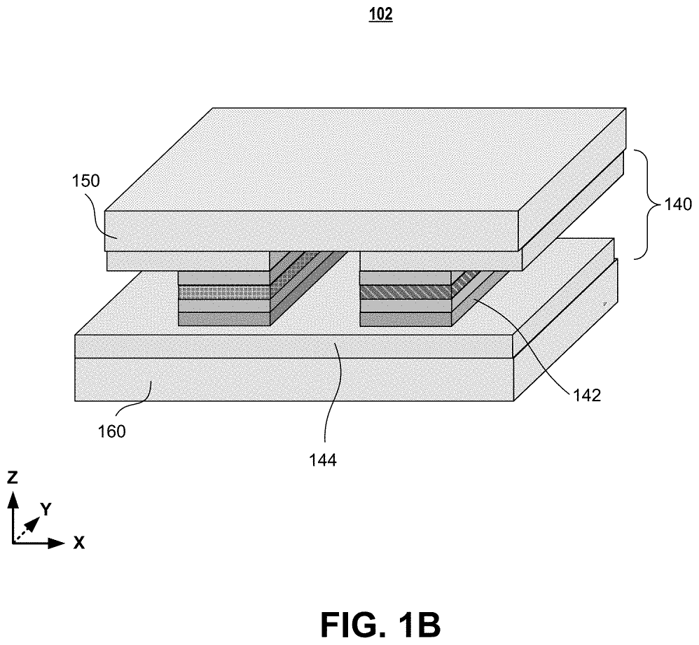

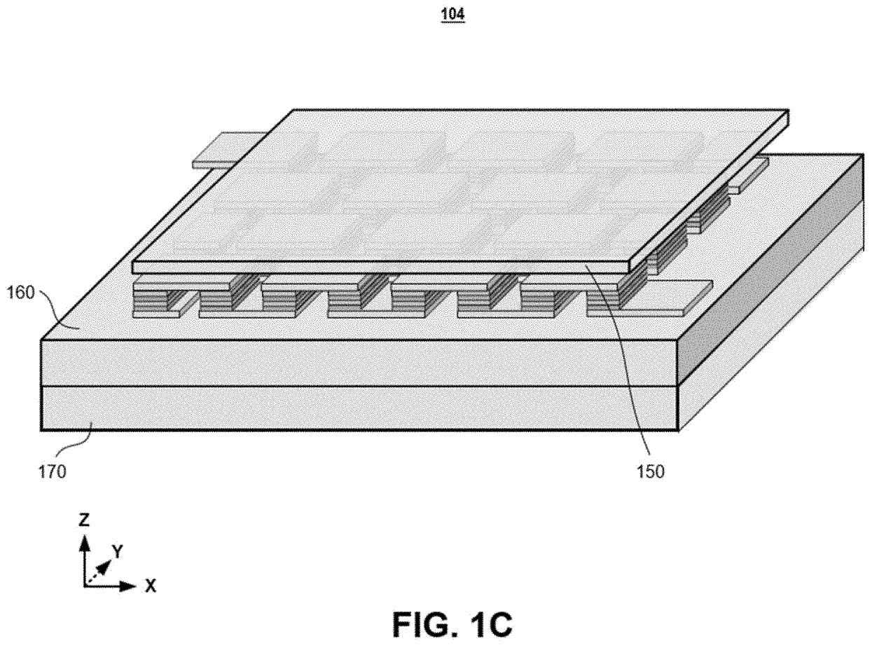

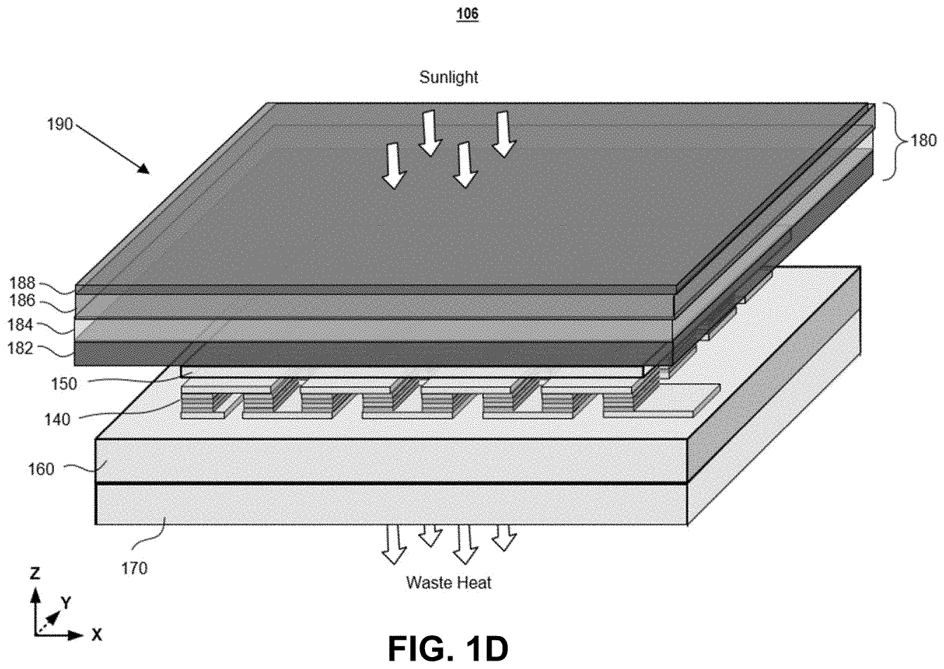

FIGS. 1A, 1B, 1C, and 1D are schematic illustrations of example process flow steps for fabricating an MJPV-NETT device 190 according to some aspects of the present disclosure. For example, the example process flow can begin with individual P-CHESS and N-CHESS epitaxial wafers (epi wafers) as described with reference to FIG. 1A and end with MJPV-NETT device 190 as described with reference to FIG. 1D. It is to be understood that the structures shown in FIGS. 1A, 1B, 1C, and 1D are not drawn to scale.

FIG. 1A illustrates P-CHESS and N-CHESS epi growth on separate substrates (e.g., GaAs wafers, Si wafers, Ge wafers, sapphire wafers, etc.), according to some embodiments. As shown in FIG. 1A, step 100 of the example process flow can include forming (e.g., growing) a P-CHESS layer 120 on a GaAs substrate 122. In some aspects, the P-CHESS layer 120 can be patterned to form P-CHESS islands to aid in the dicing of the P-CHESS layer 120 into p-type thermoelectric structures (e.g., rectangular strips). Step 100 can further include forming an N-CHESS layer 130 on a GaAs substrate 132. In some aspects, the N-CHESS layer 130 can be patterned to form N-CHESS islands to aid in the dicing of the N-CHESS layer 130 into n-type thermoelectric structures (e.g., rectangular strips). In some aspects, step 100 can further include fabricating (e.g., depositing and patterning) an electrical contact layer 134 on the P-CHESS islands and the N-CHESS islands.

FIG. 1B illustrates the fabrication of a NETT device 140, according to some embodiments. As shown in FIG. 1B, step 102 of the example process flow can include forming the NETT device 140, mounting a common heat collector device 150 to the hot side of the NETT device 140, and mounting a heat sink device 160 to the cold side of the NETT device 140. In some aspects, the NETT device 140 can include multiple pairs of CHESS thermoelectric structures, where each pair of CHESS thermoelectric structures includes a P-CHESS structure and an N-CHESS structure. Each P-CHESS structure can be disposed between electrical contacts (e.g., electrical contact metallization), solder, and electrical contacts 144 (e.g., electroplated Cu). Each N-CHESS structure can be disposed between electrical contacts (e.g., electrical contact metallization), solder 142, and electrical contacts 144 (e.g., electroplated Cu). In some aspects, the NETT device 140 can be disposed between the common heat collector device 150 (e.g., AlN) and the heat sink device 160 (e.g., AlN).

FIG. 1C illustrates the addition of a radiator device 170, according to some embodiments. As shown in FIG. 1C, step 104 of the example process flow can include mounting the radiator device 170 to the heat sink device 160. In some aspects, the radiator device 170 can include cooling structures, such as microstructures, fins, pins, heat pipes, or a combination thereof, disposed on a surface of the radiator device 170 opposite the heat sink device 160 to maximize the heat rejection provided by the radiator device 170 (e.g., by maximizing emissivity and absorptivity as well as the area of emission and absorption to achieve the lowest or highest radiator emission/absorption temperatures, as needed, thus providing the largest AT across the MJPV-NETT device 190 for maximum conversion efficiency). In some aspects, heat sink device 160 may be coupled to another cooling system or to the cooling system as well as radiator device 170.

FIG. 1D illustrates the fabrication of the MJPV-NETT device 190, according to some embodiments. As shown in FIG. 1D, step 106 of the example process flow can include mounting an MJPV device 180 to the common heat collector device 150. In some aspects, the MJPV device 180 can include a first photovoltaic layer 182, a second photovoltaic layer 184, a third photovoltaic layer 186, and an anti-reflective coating 188. In some example applications, sunlight may be AM0 for space applications, AM1.5 for terrestrial applications, or the like. The released waste heat can be understood to be the remaining energy after the NETT structures have converted some of the heat to power. That is, waste heat power output can be thought of as the total of power of incoming sunlight minus the PV power output and minus the NETT power output.

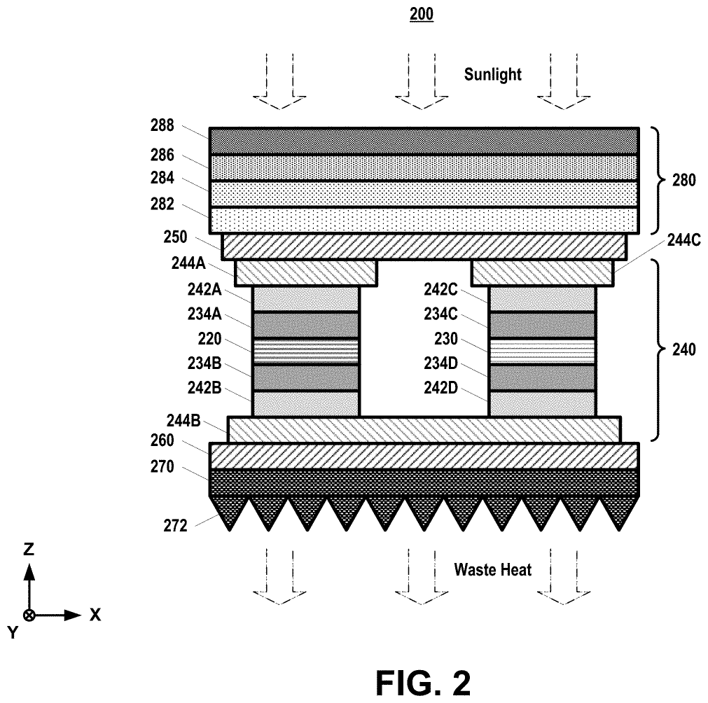

FIG. 2 shows an MJPV-NETT device 200, according to some aspects of the present disclosure or portion(s) thereof. As shown in FIG. 2, the MJPV-NETT device 200 can include a NETT device 240, a common heat collector device 250, a heat sink device 260, a radiator device 270, and an MJPV device 280. Sunlight may be as explained above for different applications (e.g., AM0, AM1.5, or the like).

In some aspects, the NETT device 240 can include multiple pairs of CHESS thermoelectric structures, where each pair of CHESS thermoelectric structures includes a P-CHESS thermoelectric structure 220 and an N-CHESS thermoelectric structure 230. Each P-CHESS thermoelectric structure 220 can be disposed between electrical contacts 234A and 234B (e.g., electrical contact metallization), solder 242A and 242B, and electrical contacts 244A and 244B (e.g., electroplated Cu). Each N-CHESS thermoelectric structure 230 can be disposed between electrical contacts 234C and 234D, solder 242C and 242D, and electrical contacts 244B and 244C.

In some aspects, each P-CHESS thermoelectric structure 220 can include a first CHESS thermoelectric material including first CHESS periods, where each of the first CHESS periods can include a first p-type semiconductor material layer disposed adjacent to a second p-type semiconductor material layer. In one example, for each of the first CHESS periods, the first p-type semiconductor material layer can include p-type Bi₂Te₃ (bismuth telluride), and the second p-type semiconductor material layer can include p-type Sb₂Te₃ (antimony telluride) or p-type Bi₂Te₃₋ₓSeₓ (bismuth selenide alloy). In another example, for each of the first CHESS periods, the first p-type semiconductor material layer can include a first periodic table Group V-VI, II-VI, or IV compound doped to form a second p-type semiconductor material, and the second p-type semiconductor material layer can include a second periodic table Group V-VI, II-VI, or IV compound doped to form a second p-type semiconductor material.

In some aspects, each N-CHESS thermoelectric structure 230 can include a second CHESS thermoelectric material including second CHESS periods, where each of the second CHESS periods includes a first n-type semiconductor material layer disposed adjacent to a second n-type semiconductor material layer. In one example, for each of the second CHESS periods, the first n-type semiconductor material layer can include n-type Bi₂Te₃ (bismuth telluride), and the second n-type semiconductor material layer can include n-type Sb₂Te₃ (antimony telluride) or n-type Bi₂Te₃₋ₓSeₓ (bismuth selenide alloy). In another example, for each of the second CHESS periods, the first n-type semiconductor material layer can include a first periodic table Group V-VI, II-VI, or IV compound doped to form a first n-type semiconductor material, and the second n-type semiconductor material layer can include a second periodic table Group V-VI, II-VI, or IV compound doped to form a second n-type semiconductor material.

In some aspects, the common heat collector device 250 can include AlN, such as an AlN layer or plate. In some aspects, the heat sink device 260 can include AlN, such as an AlN layer or plate. In some aspects, the radiator device 270 can include cooling structures 272, such as microstructures, fins, pins, heat pipes, or a combination thereof, disposed on a surface of the radiator device 270 opposite the heat sink device 260 to maximize the heat rejection provided by the radiator device 270 (e.g., by maximizing emissivity and absorptivity as well as the area of emission and absorption to achieve the lowest or highest radiator emission/absorption temperatures, as needed, thus providing the largest AT across the MJPV-NETT device 200 for maximum conversion efficiency).

In some aspects, the MJPV device 280 can include a first photovoltaic layer 282, a second photovoltaic layer 284, a third photovoltaic layer 286, and an anti-reflective coating 288.

### Example Processes for Manufacturing Nano-Engineered Thin-Film Thermoelectric (NETT) Devices for Photovoltaic Applications

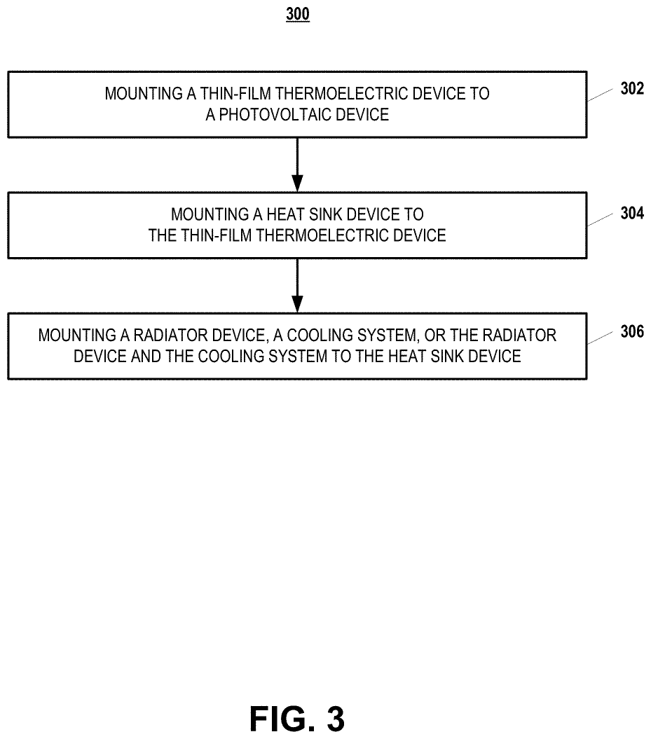

FIG. 3 is an example method 300, according to some embodiments. For example, method 300 can be used for manufacturing NETT devices for photovoltaic applications, such as MJPV-NETT devices (e.g., MJPV-NETT device 190, 200), according to some aspects of the present disclosure or portion(s) thereof. In some aspects, method 300 can provide for large area scalable fabrication of versatile thin-film thermoelectric device modules as described herein. The operations described with reference to example method 300 can be performed by, or according to, any of the systems, apparatuses, components, techniques, or combinations thereof described herein, such as those described with reference to FIGS. 1A-1D and 2 above.

At operation 302, the method 300 can include mounting a thin-film thermoelectric device to a photovoltaic device. In some aspects, the thin-film thermoelectric device can include a NETT device (e.g., NETT device 140, 240). In some aspects, the photovoltaic device can include an MJPV device (e.g., MJPV device 180, 280).

In some aspects, the thin-film thermoelectric device can include CHESS thermoelectric structures. In some aspects, the CHESS thermoelectric structures can include P-CHESS thermoelectric structures (e.g., P-CHESS layer 120, P-CHESS thermoelectric structure 220) and N-CHESS thermoelectric structures (e.g., N-CHESS layer 130, N-CHESS thermoelectric structure 230), where a pair of CHESS thermoelectric structures includes one of the P-CHESS thermoelectric structures and one of the N-CHESS thermoelectric structures. In some aspects, the thin-film thermoelectric device can include thin-film thermoelectric device modules, where the thin-film thermoelectric device modules include at least a pair of CHESS thermoelectric structures, and where the pair of CHESS thermoelectric structures includes a P-CHESS thermoelectric structure and an N-CHESS thermoelectric structure. For example, the thin-film thermoelectric device can include at least one hundred thin-film thermoelectric device modules including at least one hundred pairs of CHESS thermoelectric structures. In some aspects, the P-CHESS thermoelectric structures can include a P-CHESS thermoelectric material, and the N-CHESS thermoelectric structures can include an N-CHESS thermoelectric material.

In some aspects, the P-CHESS thermoelectric structures can include a first CHESS thermoelectric material including first CHESS periods, where each of the first CHESS periods includes a first p-type semiconductor material layer disposed adjacent to a second p-type semiconductor material layer. In one example, for each of the first CHESS periods, the first p-type semiconductor material layer can include p-type Bi₂Te₃, and the second p-type semiconductor material layer can include p-type Sb₂Te₃ or p-type Bi₂Te₃₋ₓSeₓ. In another example, for each of the first CHESS periods, the first p-type semiconductor material layer can include a first periodic table Group V-VI, II-VI, or IV compound doped to form a second p-type semiconductor material, and the second p-type semiconductor material layer can include a second periodic table Group V-VI, II-VI, or IV compound doped to form a second p-type semiconductor material.

In some aspects, the N-CHESS thermoelectric structures can include a second CHESS thermoelectric material including second CHESS periods, where each of the second CHESS periods includes a first n-type semiconductor material layer disposed adjacent to a second n-type semiconductor material layer. In one example, for each of the second CHESS periods, the first n-type semiconductor material layer can include n-type Bi₂Te₃, and the second n-type semiconductor material layer can include n-type Sb₂Te₃ or n-type Bi₂Te₃₋ₓSeₓ. In another example, for each of the second CHESS periods, the first n-type semiconductor material layer can include a first periodic table Group V-VI, II-VI, or IV compound doped to form a first n-type semiconductor material, and the second n-type semiconductor material layer can include a second periodic table Group V-VI, II-VI, or IV compound doped to form a second n-type semiconductor material.

In some aspects, the method 300 can further include forming the P-CHESS thermoelectric structures on a first substrate (e.g., GaAs substrate 122; a first Si, Ge, or sapphire wafer), dicing the P-CHESS thermoelectric structures, and disposing (e.g., bonding) the P-CHESS thermoelectric structures on a carrier substrate (e.g., glass, SiC, AlN, Al₂O₃, Si, or a flexible material such as Kapton® (poly (4, 4′-oxydiphenylene pyromellitimide))).

In some aspects, the method 300 can further include forming the N-CHESS thermoelectric structures on a second substrate (e.g., GaAs substrate 132; a second Si, Ge, or sapphire wafer), dicing the N-CHESS thermoelectric structures, and disposing (e.g., bonding) the N-CHESS thermoelectric structures on the carrier substrate.

In some aspects, the disposing the N-CHESS thermoelectric structures on the carrier substrate can include disposing a first N-CHESS thermoelectric structure adjacent to a first P-CHESS thermoelectric structure (e.g., to form an alternating pattern of p-type and n-type thermoelectric structures).

In some aspects, a diameter (e.g., 6 in) of the first substrate can be less than a diameter (e.g., 10 in) of the carrier substrate, and a diameter (e.g., 6 in) of the second substrate also can be less than the diameter of the carrier substrate.

In some aspects, the mounting of the thin-film thermoelectric device to the photovoltaic device at operation 302 can be accomplished using any suitable mechanical or other methods and include mounting the thin-film thermoelectric device to the photovoltaic device in accordance with any aspect or combination of aspects described with reference to FIGS. 1A-1D and 2 above.

At operation 304, the method 300 can include mounting a heat sink device (e.g., heat sink device 160, 260) to the thin-film thermoelectric device. In some aspects, the heat sink device can include aluminum nitride (AlN). In some aspects, the mounting of the heat sink device to the thin-film thermoelectric device at operation 304 can be accomplished using any suitable mechanical or other methods and include mounting the heat sink device to the thin-film thermoelectric device in accordance with any aspect or combination of aspects described with reference to FIGS. 1A-1D and 2 above.

At operation 306, the method 300 can include mounting a radiator device (e.g., radiator device 170, 270) to the heat sink device. In some aspects, the radiator device can include microstructures, such as fins, disposed on a surface of the radiator device opposite the heat sink to maximize the surface area of the radiator device. In some aspects, the mounting of the radiator device to the heat sink device at operation 306 can be accomplished using any suitable mechanical or other methods and include mounting the radiator device to the heat sink device in accordance with any aspect or combination of aspects described with reference to FIGS. 1A-1D and 2 above.

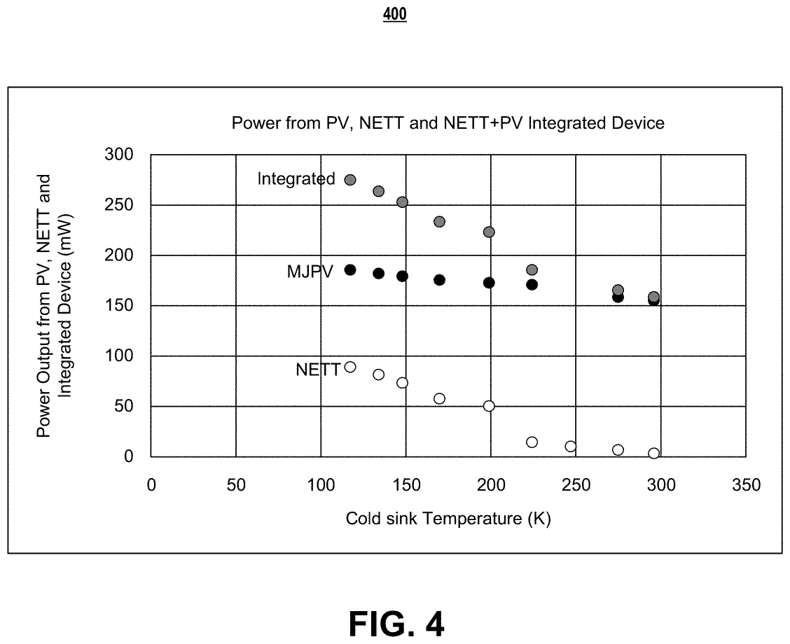

FIG. 4 shows a graph 400 of power output data of power-generating devices disclosed herein, according to some embodiments. In some aspects, the power output shown in graph 400 are for a PV device (MJPV), a NETT device, and a NETT+PV device (integrated). The power output is plotted with respect to a temperature of a cold sink (e.g., a heat sink with active cooling, e.g., liquid cooling). The vertical axis represents power output. The horizontal axis represents the cold sink temperature. It is shown that colder temperatures increases the power output of the two devices that have a NETT. When cold sink temperature is at approximately 117 K, the PV array itself can be at approximately 183 K. An external difference in temperature of approximately 66 K is present across the NETT device. It can be seen that the integrated PV-NETT device experiences significantly enhanced power output when the NETT is actively cooled.

In some aspects, the integrated PV-NETT device can provide substantial increase in power output. The data shows a maximum power output of approximately 275 mW in some extreme cold sink scenarios, compared to approximately 159 mW by the MJPV at room temperature (e.g., approximately 300 K).

In some aspects, devices and functions described herein for space applications can also be adapted to terrestrial applications. A heat-sink can be air-cooled (with various heat-sinks) or liquid-cooled (e.g., water, refrigerant, cryogenics, or the like). In space, cooling of heat-sink is achieved by radiating heat to outer space at ˜4K. On earth, it is possible to use fluid-cooling, or other cooling method(s) to treat the waste heat coming from the NETT. A cooling system can include systems that exchange heat via air (e.g., flowing air through fins on the heat sink), via a liquid (e.g., a refrigerant conduit coupled to the heat sink), via a phase-change medium (e.g., liquid to gas), or the like. A cooling system may be closed-loop fluid system. In some aspects, a cooling system can be used together with radiator device 170. A cooling system can be used in terrestrial applications as well as space applications.

In some aspects, a non-limiting example of operating conditions for a NETT on Earth can be at −30° C. (e.g., away from Earth's equator). With clear skies, a PV device can operate at approximately 40-60° C. (e.g., 50° C.). Such conditions are closer to simulating the coldness of space. The efficiency regarding space use of NETT as described above can also be applicable to such terrestrial-based uses of NETT-photovoltaic devices.

In some aspects, another non-limiting example of terrestrial-based cold conditions for a NETT can be via the use of cooling systems (e.g., refrigerant, cryogenics, or the like). For example, an actively cooled NETT can operate at −80° C. (e.g., on the backside). As before, in clear skies, a PV device can operate at approximately 40-60° C. (e.g., 50° C.). In this scenario, the NETT can operate between 50° C. and −80° C., adding to the efficiency of the PV operating at 50° C. To clarify further, a coolant loop can be close-looped. The PV-NETT is unlikely to warm up very much considering the relative weakness of solar power density on Earth (e.g., 100 mW/cm²). Therefore, coolant can flow to at −80° C. to the back of NETT and leave out as −75° C. To complete a loop cycle, the coolant can be cooled back to −80° C. using a small input power. As before, the efficiency regarding space use of NETT as described above can be applicable to this aspect of a PV-NETT used on Earth.

It is to be understood that the phraseology or terminology herein is for the purpose of description and not of limitation, such that the terminology or phraseology of the present specification is to be interpreted by those skilled in relevant art(s) in light of the teachings herein.

The term “substrate” as used herein describes a material onto which material layers are added. In some aspects, the substrate itself can be patterned and materials added on top of it can also be patterned, or can remain without patterning. The skilled artisan will appreciate that, in the context of such alternative applications, any use of the terms “wafer” or “die” herein may be considered as synonymous with the more general terms “substrate” or “target portion”, respectively. The substrate referred to herein can be processed, before or after exposure, in for example a track unit (a tool that applies a layer of resist to a substrate and develops the exposed resist), a metrology unit and/or an inspection unit. Where applicable, the disclosure herein can be applied to such and other substrate processing tools. Further, the substrate can be processed more than once, for example in order to create a multi-layer IC, so that the term substrate used herein may also refer to a substrate that already contains multiple processed layers.

The examples disclosed herein are illustrative, but not limiting, of the embodiments of this disclosure. Other suitable modifications and adaptations of the variety of conditions and parameters normally encountered in the field, and which would be apparent to those skilled in the relevant art(s), are within the spirit and scope of the disclosure.

While specific aspects of the disclosure have been described above, it will be appreciated that the aspects can be practiced otherwise than as described. The description is not intended to limit the embodiments of the disclosure.

It is to be appreciated that the Detailed Description section, and not the Background, Summary, and Abstract sections, is intended to be used to interpret the claims. The Summary and Abstract sections may set forth one or more but not all example embodiments as contemplated by the inventor(s), and thus, are not intended to limit the present embodiments and the appended claims in any way.

Some aspects of the disclosure have been described above with the aid of functional building blocks illustrating the implementation of specified functions and relationships thereof. The boundaries of these functional building blocks have been arbitrarily defined herein for the convenience of the description. Alternate boundaries can be defined so long as the specified functions and relationships thereof are appropriately performed.

The foregoing description of the specific aspects of the disclosure will so fully reveal the general nature of the aspects that others can, by applying knowledge within the skill of the art, readily modify and/or adapt for various applications such specific aspects, without undue experimentation, without departing from the general concept of the present disclosure. Therefore, such adaptations and modifications are intended to be within the meaning and range of equivalents of the disclosed aspects, based on the teaching and guidance presented herein.

The breadth and scope of the present disclosure should not be limited by any of the above-described example aspects or embodiments, but should be defined only in accordance with the following claims and their equivalents.

What is claimed is:

1. A method comprising:
mounting a thin-film thermoelectric device to a photovoltaic device;
mounting a heat sink device to the thin-film thermoelectric device; and
mounting a radiator device, a cooling system, or the radiator device and the cooling system to the heat sink device.

2. The method of claim 1, wherein:
the thin-film thermoelectric device comprises controlled hierarchical engineered superlattice structure (CHESS) thermoelectric structures; and
the CHESS thermoelectric structures comprise p-type CHESS (P-CHESS) thermoelectric structures and n-type CHESS (N-CHESS) thermoelectric structures.

3. The method of claim 2, wherein:
the thin-film thermoelectric device comprises thin-film thermoelectric device modules;
the thin-film thermoelectric device modules comprises at least a pair of the CHESS thermoelectric structures; and
the pair of the CHESS thermoelectric structures comprises a P-CHESS thermoelectric structure and an N-CHESS thermoelectric structure.

4. The method of claim 2, wherein the P-CHESS thermoelectric structures comprise a first p-type semiconductor material layer disposed adjacent to a second p-type semiconductor material layer.

5. The method of claim 4, wherein:
the first p-type semiconductor material layer comprises p-type bismuth telluride (Bi₂Te₃); and
the second p-type semiconductor material layer comprises p-type antimony telluride (Sb₂Te₃) or a p-type bismuth selenide alloy (Bi₂Te₃₋ₓSeₓ).

6. The method of claim 4, wherein:
the first p-type semiconductor material layer comprises a first periodic table Group V-VI compound doped to form a first p-type semiconductor material; and
the second p-type semiconductor material layer comprises a second periodic table Group V-VI compound doped to form a second p-type semiconductor material.

7. The method of claim 2, wherein the N-CHESS thermoelectric structure comprises a first n-type semiconductor material layer disposed adjacent to a second n-type semiconductor material layer.

8. The method of claim 7, wherein:
the first n-type semiconductor material layer comprises n-type bismuth telluride (Bi₂Te₃); and
the second n-type semiconductor material layer comprises n-type antimony telluride (Sb₂Te₃) or an n-type bismuth selenide alloy (Bi₂Te₃₋ₓSeₓ).

9. The method of claim 7, wherein:
the first n-type semiconductor material layer comprises a first periodic table Group V-VI compound doped to form a first n-type semiconductor material; and
the second n-type semiconductor material layer comprises a second periodic table Group V-VI compound doped to form a second n-type semiconductor material.

10. The method of claim 2, further comprising:
forming the P-CHESS thermoelectric structures on a first substrate;
dicing the P-CHESS thermoelectric structures;
disposing the P-CHESS thermoelectric structures on a carrier substrate;
forming the N-CHESS thermoelectric structures on a second substrate;
dicing the N-CHESS thermoelectric structures; and
disposing the N-CHESS thermoelectric structures on the carrier substrate.

11. The method of claim 10, wherein the disposing the N-CHESS thermoelectric structures on the carrier substrate comprises disposing a first N-CHESS thermoelectric structure adjacent to a first P-CHESS thermoelectric structure.

12. The method of claim 10, wherein each of a first diameter of the first substrate and a second diameter of the second substrate is less than a third diameter of the carrier substrate.

13. The method of claim 1, wherein the thin-film thermoelectric device comprises at least one hundred thin-film thermoelectric device modules.

14. The method of claim 1, wherein the photovoltaic device comprises a multi-junction photovoltaic (MJPV) device.

15. The method of claim 1, wherein the photovoltaic device comprises a concentrator photovoltaic device.

16. The method of claim 1, wherein the photovoltaic device comprises a flat-plate photovoltaic device.

17. The method of claim 1, wherein the heat sink device comprises aluminum nitride (AlN).

18. The method of claim 1, wherein the radiator device comprises microstructure fins disposed on a surface of the radiator device opposite the heat sink.

19. A nano-engineered thin-film thermoelectric (NETT) device manufactured according to the method of claim 1.

20. An apparatus, comprising:
a photovoltaic device;
a thin-film thermoelectric device mounted to the photovoltaic device;
a heat sink device mounted to the thin-film thermoelectric device; and
a radiator device mounted to the heat sink device.

21. The apparatus of claim 20, wherein:
the thin-film thermoelectric device comprises controlled hierarchical engineered superlattice structure (CHESS) thermoelectric structures; and
the CHESS thermoelectric structures comprise p-type CHESS (P-CHESS) thermoelectric structures and n-type CHESS (N-CHESS) thermoelectric structures.

22. The apparatus of claim 20, wherein the photovoltaic device comprises a multi-junction photovoltaic (MJPV) device.
